(19) United States
(12) Patent Application Publication
(10) Pub. No.: US 2004/0026695 A1
(43) Pub. Date: Feb. 12, 2004

(54) Electronic device comprising electric circuits and a photosensitive zone and a method of manufacturing same

(76) Inventor: Roy Francois, Seyssins (FR)

Correspondence Address: Andre M. Szuwalski, Jenkens & Gilchrist, P.C., Suite 3200, 1445 Ross Ave., Dallas, TX, 75202-2799, US

(21) Appl. No.: 10/446,509

(22) Filed: May 27, 2003

(30) Foreign Application Priority Data
May 27, 2002 (FR) 02 06432

(51) Int. Cl. H01L 29/04; H01L 31/036; H01L 31/0376; H01L 31/20

(52) U.S. Cl. 257/53

(57) ABSTRACT

An electronic device includes a photosensitive zone and electric circuits distributed within an insulator. The photosensitive zone and the insulator are placed on the surface of a substrate. The insulator extends to a first height from the surface of the substrate, and a transparent material covers the photosensitive zone to a second height from the surface of the substrate. The second height is less than said first height. According to an advantageous method of manufacturing the electronic device, the transparent material is identical to the insulator, and the method comprises a step of removing the transparent material between the first height and the second height.

### PRIORITY CLAIM

The present application claims foreign priority from French Application for Patent No. 02 06432 filed May 27, 2002, the disclosure of which is hereby incorporated by reference.

### BACKGROUND OF THE INVENTION

1. Technical Field of the Invention

The present invention relates to an electric device comprising a semiconductor support on which a photosensitive cell and electronic circuits are prepared. More specifically, it relates to means for optical coupling between an entrance face for the light entering the cell and a photosensitive element arranged at the surface of the semiconductor support.

2. Description of Related Art

Many optical components incorporate a photosensitive cell. Such components are, for example, optical detectors comprising a single element, or cell, sensitive to the light incident on an entrance face of this cell. Optical detectors formed by a matrix of photosensitive cells juxtaposed side by side, whose respective entrance faces are located in the same plane, may also be involved. In this case, the cells may be distinguished by their location within the matrix, for example for detecting the position of a point of light on the surface of this matrix.

Photosensitive cells belonging to a matrix may also be distinguished by the wavelength of the light to which each of them is sensitive, or else distinguished by a combination of the wavelength of sensitivity and the location of the cell within the matrix, for example for detecting polychromatic light images.

In such components, the photosensitive cell is small in order to obtain good spatial resolution. For example, it has an entrance face for the light of dimensions approximately equal to 5.6 μm×5.6 μm (where μm means a micrometer), which limits the amount of light entering the photosensitive cell.

In general, the cell occupies a cylindrical overall volume, the cross section of which, in a plane orthogonal to the main axis of this cylinder, is of varied shape. When the photosensitive cell is shown in section in a plane containing its main axis, this axis is in general shown along the vertical, with the entrance face at the top and the photosensitive element at the bottom. Hereinafter, the terms “lower” and “upper”, “on” and “under”, used in relation to denoting the elements constituting the photosensitive cell or the photosensitive matrix, are so used with reference to this convention. Thus, the upper part of the photosensitive cell is bounded by the entrance face, and its lower part by a semiconductor support or substrate, whose surface turned towards the inside of the cell is substantially plane and parallel to the entrance face.

In general, the photosensitive element includes a surface portion of the semiconductor substrate which is specially treated in order to fulfil this function, and which is hereinafter denoted photosensitive zone. In this zone, in order to increase the sensitivity of light detection, the inner surface of the substrate may have been made particularly uneven, but it retains a substantially planar overall geometry.

Inside the cell, the surface of the substrate comprises, apart from the aforementioned photosensitive zone, a portion of surface occupied by electronic components incorporated into the cell. These components are part of the means for reading and controlling the photosensitive cell. The photosensitive zone therefore has a smaller surface area than the surface area of the entrance face. For example, the dimensions of the photosensitive zone are 2 μm×2 μm for an entrance face of 5.6 μm×5.6 μm. The photosensitive zone is centered with respect to the entrance face, and therefore centered with respect to the axis of the cell. As for the electronic components inside the cell, they are placed outside the photosensitive zone, on the periphery thereof.

Consequently, photosensitive cells of this type are designed in order to receive convergent light on their entrance face, such that all the light which enters the cell via its entrance face reaches the photosensitive zone, without any part of this light being lost due to it illuminating electronic components incorporated within the cell rather than the photosensitive zone.

A photosensitive cell of this type may be used with light which is made convergent by means of standard optical devices if the entrance face and the photosensitive zone are separated by a distance of approximately around 6 μm. If this distance is too great, the standard devices by means of which light incident on the entrance face of photosensitive cells is made convergent are no longer suitable. Now such a distance, for example greater than 6 μm, may appear when the substrate additionally bears electronic components made in the form of several metallization levels. This is because, in the CMOS technologies currently used for manufacturing electronic circuits, five or six metallization levels are distributed within as many layers of insulator placed on the surface of the substrate. These layers of insulator then represent a total thickness greater than 10 μm above the surface of the substrate, or even round about 12 μm. When the photosensitive zone is borne by the surface of the substrate and when the entrance face for the light is located on the upper surface of the insulator, the convergence focus of convergent light beams as usually used and sent through the entrance face of the cell is located above the photosensitive zone, at about 4 to 6 μm therefrom. The light beam then diverges between this focus and the photosensitive zone, resulting in a cross section of the light beam on the surface of the substrate which is greater than the surface area of the photosensitive zone. Part of the light entering the cell through the entrance face is consequently lost, causing a reduction in the sensitivity of the cell.

### SUMMARY OF THE INVENTION

The present invention provides a configuration for a photosensitive cell borne by a substrate which does not have this drawback, although the substrate additionally bears electronic circuits distributed in an insulator extending to a preset height above the surface of the substrate.

A first aspect of the present invention relates to an electronic device which comprises a substrate having a surface, at least one insulator placed above at least one first portion of the surface of the substrate to a first height from the surface of the substrate, and electric circuits distributed within the insulator. The device also comprises at least one photosensitive zone placed in at least one second portion of the surface of the substrate separate from said first portion, and at least one first transparent material covering said photosensitive zone to a second height from the surface of the substrate. According to the invention, said second height is less than said first height. Thus, the entrance face of the photosensitive cell borne by the upper surface of said first transparent material is lower than the upper surface of the insulator within which the electric circuits are distributed. The distance between the entrance face and the photosensitive zone is then compatible with the convergent light beams usually used.

Optionally, the photosensitive cell comprises at least one convergent optical device arranged above the first transparent material, on a side of the first transparent material away from the photosensitive zone. This convergent device may comprise a convergent microlens, made in a manner known to a person skilled in the art on the upper surface of the first transparent material. Such a microlens usually has a focal length in this first transparent material of about 4 to 6 μm, which then corresponds approximately to the distance between the entrance face of the photosensitive cell and the photosensitive zone. An additional convergent lens placed above the entrance face of the cell, at a preset distance therefrom, may be combined with the microlens. In the case of a matrix of photosensitive cells borne by the substrate, a microlens is arranged above each cell, while the additional convergent lens is common to all the cells of the matrix.

Furthermore, the photosensitive cell may comprise a second transparent material placed above the first transparent material covering the photosensitive zone, on a side of the first transparent material away from the photosensitive zone, to a third height from the surface of the substrate. This third height is then greater than the second height. In addition, the optical refractive index of the second transparent material is greater than the optical refractive index of the first transparent material. It may optionally also be greater than the index of the insulator between said third and first heights. Such a second transparent material placed in this way makes it possible to increase the distance between the entrance face for the light entering the cell and the photosensitive zone while retaining a focus of convergence of the light beams usually used, which focus is located at the surface of the substrate. Furthermore, it makes it possible to place electronic components for controlling the photosensitive cell inside the first transparent material without causing loss of part of the light entering the cell via the entrance face. This is because such electronic components may be placed in a part of the first transparent material which is not traversed by a convergent light beam entering the cell, since this beam converges at the second transparent material.

In the presence of the second transparent material, any convergent optical device (i.e., the convergent microlens in the example in question) is then arranged above the second transparent material, on a side of the second transparent material away from the first transparent material and from the photosensitive zone.

When said first and third heights are chosen to be equal to each other, the light entrance face of the photosensitive cell and the upper surface of the insulator within which the electric circuits are distributed are then located in the same plane parallel to the surface of the substrate.

When the electric circuits are made by repeatedly using a planarization process of the CMP (“Chemical Mechanical Polishing”) or Damascene type known to a person skilled in the art, the insulator may comprise at least four layers superimposed in a direction perpendicular to the surface of the substrate. It may especially comprise five or six layers, leading to a total height of insulator incorporating electric circuits, of about 10 to 12 μm. In this case, said second height is preferably less than or equal to a height from the surface of the substrate corresponding to the first three layers of the insulator counting from the surface of the substrate.

The insulator within which the electric circuits and the first transparent material are distributed may have respective optical refractive indices which are identical. These two materials may also be identical. In this case, the lower layers of the insulator placed on the substrate may then be continually extended between the first and second surface portions of the substrate.

In particular embodiments of the invention, the various insulator layers in which the electric circuits are distributed may comprise of different respective insulators. Similarly, the first transparent material and, optionally, the second transparent material may be replaced respectively by stacks of several layers of varied constituent transparent materials. In this case, the optical refractive indices to be taken into consideration in the invention for the insulator, the first transparent material and, optionally, the second transparent material, are the averages of the optical refractive indices of their respective constituent materials, weighted by the thicknesses of the corresponding layers.

A second aspect of the invention relates to a method of manufacturing a particular electronic device of the above type. This method comprises the following steps:

a) a photosensitive zone is prepared in at least one second portion of a surface of a substrate;

b) at least one layer of transparent insulator is prepared on the surface of the substrate over said second portion of the surface of the substrate and at least one first portion of the surface of the substrate separate from said second portion, the layer of transparent insulator extending to a first height from the surface of the substrate, and electric circuits are distributed in said layer of insulator over said first surface portion of the substrate;

c) part of the transparent insulator located directly in line with the photosensitive zone is removed so as to form a cavity, said cavity having a bottom which is substantially parallel to the surface of the substrate and located at a second height from the surface of the substrate which is less than said first height. This removal may be carried out, for example, using an etching plasma.

In one advantageous embodiment of the method of the invention, during step b), at least four layers of the insulating and transparent material are superimposed in a direction perpendicular to the surface, and together extending to said first height. During step c), part of the insulating and transparent material directly in line with the photosensitive zone may then be removed such that the second height from the surface of the substrate is less than or equal to a height, from the surface of the substrate corresponding to the first three layers of the insulator counting from the surface of the substrate.

In an additional step occurring after step c), a convergent optical device may be arranged above the photosensitive zone, on a side of said insulating and transparent material away from the substrate. The convergent optical device may comprise a microlens placed on the upper surface of the insulating and transparent material in the cavity.

As a variant, the method of the invention further comprises a step d) in which the cavity is at least partially filled with another transparent material, the optical refractive index of said other transparent material being greater than the optical refractive index of the transparent insulator.

The convergent optical device may then be arranged during a step e) carried out after step d), on a side of said other transparent material away from the substrate and from the photosensitive zone. This device may still be a microlens, placed on the upper surface of said other transparent material.

### BRIEF DESCRIPTION OF THE DRAWINGS

A more complete understanding of the method and apparatus of the present invention may be acquired by reference to the following Detailed Description when taken in conjunction with the accompanying Drawings wherein:

FIG. 1 is a sectional view of a substrate bearing electric circuits and a photosensitive cell according to a first embodiment of the invention; and

FIG. 2 is a sectional view of a substrate bearing electric circuits and a photosensitive cell according to a second embodiment of the invention.

### DETAILED DESCRIPTION OF THE DRAWINGS

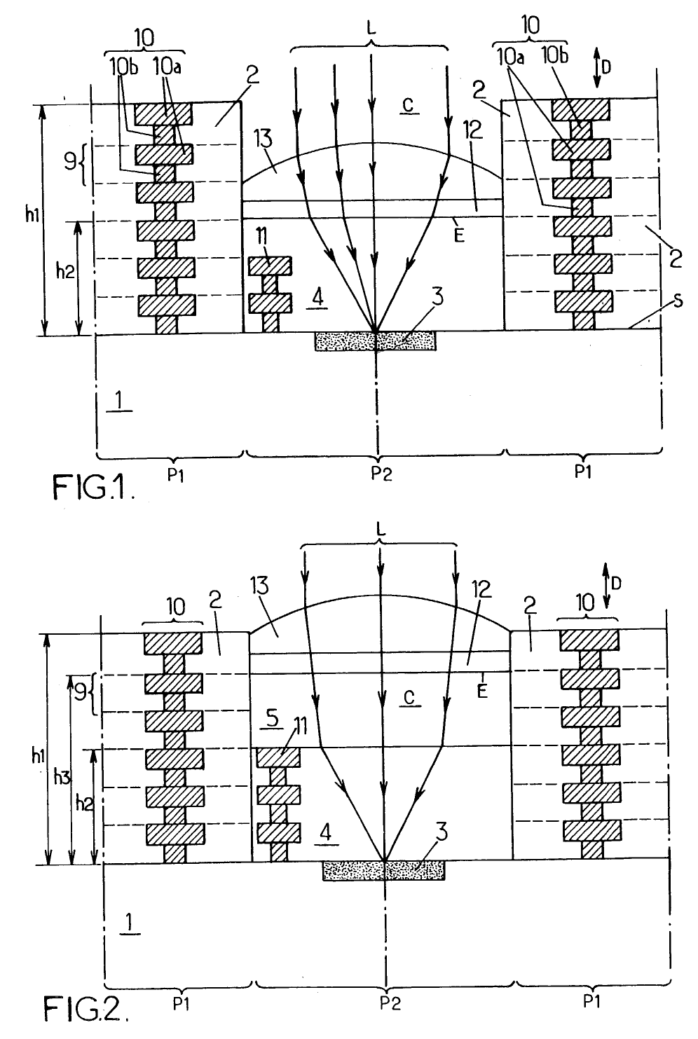

In FIG. 1, a substrate 1, for example made of single crystal silicon, comprises a photosensitive zone 3 on a plane surface S of this substrate. This photosensitive zone 3 is placed in a portion P2 of the surface S, and for example comprises a junction zone of a photodiode prepared by implantation of doping species in part of the portion P2 of the surface S. In a manner known to a person skilled in the art, a photodiode, reverse biased with respect to the direction of conduction of an electric current associated with the implanted doping species, allows the passage of an electric current depending on the light intensity received on its junction surface. Optionally, the portion P2 of the surface S may comprise several, or even a large number, of photosensitive zones 3 so as to form a matrix of juxtaposed photosensitive zones.

The axis of the photosensitive cell is then perpendicular to the surface S of the substrate 1, and cuts the surface S at a point located at the center of the photosensitive zone 3. This axis of the cell is parallel to the direction D shown in FIG. 1.

Above a portion P1 of the surface S adjacent to the portion P2 of the surface S and separate therefrom, electric circuits 10 are prepared according to a standard technology, called planarizing technology. These electric circuits 10 especially comprise metal links, for example made of copper, arranged in the form of lines 10a parallel to the surface of the substrate 1. They also comprise connections 10b placed between some of the lines 10a. These connections 10b are arranged in the direction D and are known by the name of “vias”. The lines 10a and the connections 10b are, for example, placed at superimposed levels along the direction D, called metallization levels. Each metallization level is created within a respective layer 9 of electrical insulator 2, for example made of silica SiO₂ or based on silica, parallel to the surface S. This layer 9 of electrical insulator 2 especially provides a mechanical support function for the electric circuits 10. The layers 9 of electrical insulator 2, with their respective metal circuits 10, are successively prepared on the surface S, starting from this surface, at the portion of surface P1. Each layer 9 has, for example, a thickness of about 2 μm. A stack of layers having a height h1 of about 12 μm corresponds, for example, to six superimposed layers incorporating six metallization levels.

At the surface portion P2 which comprises the photosensitive zone 3, a first transparent material 4 covers the substrate 1. This first material 4 is preferably also made of silica.

In an advantageous implementational embodiment of the invention, the first transparent material 4 is prepared at the same time as the first layers 9 of electrical insulator 2 present at the surface portion P1. For this, each of the six silica layers 9 is prepared simultaneously on the join of the two portions P1 and P2 of the surface S, but have no electric circuits in the photosensitive zone 3. Optionally, small electric circuits 11 may be incorporated in the layers 9 on the surface portion P2, outside the photosensitive zone 3. Such circuits 11, belonging to the photosensitive cell, especially allow read and initialization operations thereof.

A mask is then deposited by photolithography on top of the layers 9, which covers them over the portion P1 of the surface S. The assembly is then exposed to a plasma for directional etching according to a method known to a person skilled in the art (“dry etching”). The material corresponding to the three upper silica layers 9 is then removed by the plasma, forming the cavity C. The etching is stopped when a height h2 of residual silica in the zone P2 is reached, which, for example, corresponds to the total height of the three lower silica layers 9. The height h2 is, for example, equal to about 6 μm.

According to a first configuration of the photosensitive cells of the invention, the upper surface of the transparent material 4 constitutes the entrance face E for the light entering the photosensitive cell.

The preparation of this photosensitive cell, or of the cells in the case of a matrix, is then optionally completed by depositing a colored filter 12 over the entrance face E of each photosensitive cell. When the surface portion P2 comprises a matrix of photosensitive cells, colored filters 12 having three complementary colors may be distributed over the entrance faces E of adjacent photosensitive cells according to a known pattern, in order to construct color information at each point of the matrix.

Furthermore, the preparation of the cell or cells is continued with the production of a microlens 13 on top of the colored filter 12 of each photosensitive cell. This microlens 13 is obtained, for example, in a manner known to a person skilled in the art, by depositing a small amount of solid transparent material, capable of liquefying on moderate heating, onto the upper surface of the colored filter 12. Such a material may be organic, such as a resin chosen for its surface tension value in the liquid state. When it is heated, it then takes a shape corresponding approximately to part of a sphere and constitutes a planar-convex lens on top of the entrance face E of the photosensitive cell.

When a parallel beam of light L is sent into the photosensitive cell, through the entrance face E, in a direction approximately parallel to the direction D, this beam is made convergent by the microlens 13. According to the invention, by virtue of the arrangement of the transparent material 4 with a suitable thickness h2, less than the height h1, the light beam L converges at a point located approximately on the surface S. Thus, all the rays entering the photosensitive cell through its entrance face E arrive at the photosensitive zone 3, although the latter has transverse dimensions, that is to say, in the plane of the surface S, less than the dimensions of the entrance face E in a plane parallel to the surface S. As a result, the electric circuits 11 placed inside the photosensitive cell do not reduce the light which reaches the photosensitive zone 3.

FIG. 2 shows a second configuration of photosensitive cells according to the invention. Such photosensitive cells are obtained by a method, a first part of which is identical to that of the method described above. The cavity C, formed on removing the transparent material 4, is filled with a transparent filling material 5 to a height h3 above the surface S, for example of about 10 μm. In a preferred manner, the optical refractive index of the filling material 5 is high, in particular greater than that of the silica forming the insulating and transparent material 2 which also acts as first transparent material 4 in the present example. The filling material 5 may, for example, be tantalum oxide Ta₂O₅, titanium oxide TiO₂, zirconium oxide ZrO₂, yttrium oxide Y₂O₃, tin oxide SnO₂, or an alloy of some of these oxides. Such an alloy may also incorporate silica SiO₂, in a preset proportion, in order to have a suitable optical refractive index. The filling material 5 may also be of the transparent nitride type, such as silicon nitride Si₃N₄, aluminium nitride AlN, zirconium nitride Zr₃N₄, tantalum nitride TaN, and the like, or of the oxynitride type with one or more associated metals. Organic materials of a type close to those used for the microlenses may also be used. The upper surface of the filling material 5 then forms the entrance face E of the photosensitive cell.

The preparation of the cell is then continued in the manner already described, by proceeding to the optional deposition of the colored filter 12 and the production of the microlens 13 on the upper surface of the filling material 5.

In this second configuration of the photosensitive cell, because of the microlens 13, a first convergence of a parallel light beam L sent to the entrance face E of the photosensitive cell occurs in the filling material 5. This first convergence makes it possible to place in the cell, within the insulating and transparent material 2, electric circuits 11 which are larger than those compatible with the first configuration of photosensitive cell illustrated in FIG. 1. The beam is focused at the end of a second convergence, occurring on the insulating and transparent material 2. By virtue of the high optical refractive index of the filling material 5, the first convergence is limited, so much so that the convergence focus of the beam of parallel light L is still located in the photosensitive zone 3.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. An electronic device comprising:
a substrate having a surface with a first portion and a second portion;
at least one insulator placed above at least the first portion of the surface of the substrate to a first height from the surface of the substrate;
electric circuits distributed within the insulator;
at least one photosensitive zone placed in the second portion of the surface of the substrate separate from said first portion; and
at least one first transparent material covering said photosensitive zone to a second height from the surface of the substrate, wherein said second height is less than said first height.

2. The device according to claim 1, further comprising at least one convergent optical device arranged above the first transparent material, on a side of the first transparent material away from the photosensitive zone.

3. The device according to claim 2, wherein the convergent optical device comprises a convergent microlens.

4. The device according to claim 1, further comprising a second transparent material which is placed above the first transparent material covering the photosensitive zone, on a side of the first transparent material away from the photosensitive zone, the first and the second transparent materials having respective optical refractive indices, wherein the optical refractive index of the second transparent material is greater than the optical refractive index of the first transparent material.

5. The device according to claim 4, wherein the insulator has a refractive index less than the refractive index of the second transparent material.

6. The device according to claim 4, further comprising at least one convergent optical device arranged above the second transparent material, on a side of the second transparent material away from the first transparent material and from the photosensitive zone.

7. The device according to claim 6, wherein the convergent optical device comprises a convergent microlens.

8. The device according to claim 1, wherein the insulator and the first transparent material have respective optical refractive indices which are identical.

9. The device according to claim 1, wherein the insulator comprises at least four layers superimposed in a direction perpendicular to the surface of the substrate.

10. The device according to claim 9, wherein said second height is less than or equal to a height from the surface of the substrate corresponding to the first three layers of the insulator counting from the surface of the substrate.

11. A method of manufacturing an electronic device comprising:
a) preparing a photosensitive zone in at least one first portion of a surface of a substrate;
b) preparing at least one layer of transparent insulator on the surface of the substrate covering the first and a second portion of the surface of the substrate separate from the first portion, the layer of transparent insulator extending to a first height from the surface of the substrate and including electric circuits distributed therein over said second portion of the substrate; and
c) removing part of the transparent insulator located over the photosensitive zone so as to form a cavity, said cavity having a bottom which is substantially parallel to the surface of the substrate and located at a second height from the surface of the substrate which is less than said first height.

12. The method according to claim 11, wherein removing the part of the transparent insulator located over the photosensitive zone is accomplished using a plasma.

13. The method according to claim 11, wherein, during b), at least four layers of the transparent insulator are prepared, superimposed in a direction perpendicular to the surface.

14. The method according to claim 13, wherein, during c), part of the transparent insulator over the photosensitive zone is removed such that the second height from the surface of the substrate is less than or equal to a height from the surface of the substrate corresponding to the first three layers of the insulator in which electric circuits are distributed, these layers being counted from the surface of the substrate.

15. The method according to claim 11, further comprising, after c), arranging a convergent optical device above the photosensitive zone, on a side of said transparent insulator away from the substrate.

16. The method according to claim 11, further comprising:
d) at least partially filling the cavity with another transparent material, the optical refractive index of said other transparent material being greater than the optical refractive index of the transparent insulator.

17. The method according to claim 16, further comprising, after d):
e) arranging a convergent optical device on a side of said other transparent material away from the substrate and from the photosensitive zone.

18. A device, comprising:
a substrate including a photosensitive element formed therein; and
a transparent material formed over a top surface of a substrate to a first height, the transparent material including a cavity formed therein at a location above the photosensitive element to define a region of transparent material having a second height which is less than the first height.

19. The device of claim 18 wherein the second height is selected such that light incident on the cavity converges on the photosensitive element.

20. The device of claim 18 further including an optical element positioned in the cavity over the photosensitive element.

21. The device of claim 18 further including a colored filter layer positioned in the cavity.

22. The device of claim 18 further including an additional transparent material positioned in the cavity.

23. The device of claim 22 wherein the additional transparent material substantially fills the cavity.

24. The device of claim 22 wherein the additional transparent material has an index of refraction which exceeds an index of refraction for the transparent material.

25. The device of claim 22 further including an optical element positioned on the additional transparent material over the photosensitive element.

26. The device of claim 22 further including a colored filter layer positioned on the additional transparent material.

27. A method of manufacture comprising:
fabricating a photosensitive element in a substrate material;
covering the substrate material with a transparent insulating material to a first height; and
forming a cavity in the transparent insulating material at a location above the photosensitive element to define a region of transparent insulating material having a second height which is less than the first height.

28. The method of claim 27 wherein the second height is selected such that light incident on the cavity converges on the photosensitive element.

29. The method of claim 27 further including positioning an optical element in the cavity over the photosensitive element.

30. The device of claim 27 further including positioning a colored filter layer in the cavity.

31. The method of claim 27 further including positioning an additional transparent material in the cavity.

32. The method of claim 31 wherein the additional transparent material substantially fills the cavity.

33. The method of claim 31 wherein the additional transparent material has an index of refraction which exceeds an index of refraction for the transparent insulating material.

34. The device of claim 31 further including positioning an optical element on the additional transparent material over the photosensitive element.

35. The device of claim 31 further including positioning a colored filter layer on the additional transparent material.
